(19) United States
(12) Patent Application Publication
(10) Pub. No.: US 2026/0186173 A1
(43) Pub. Date: Jul. 2, 2026

(54) ANTISTATIC COATING AND DISPLAY PANEL INCLUDING THE SAME

(71) Applicant: Everdisplay Optronics (Shanghai) Co., Ltd., Shanghai (CN)

(72) Inventors: Pingping ZHANG, Shanghai (CN); Hsin Chih LIN, Shanghai (CN); Sizhen CAO, Shanghai (CN)

(73) Assignee: Everdisplay Optronics (Shanghai) Co., Ltd., Shanghai (CN)

(21) Appl. No.: 18/846,682

(22) PCT Filed: Nov. 7, 2023
(86) PCT No.: PCT/CN2023/130221

§ 371 Date: Sep. 13, 2024

(30) Foreign Application Priority Data
Oct. 24, 2023 (CN) 202311388162.2

(51) Int. Cl. G02B 1/16; G02B 1/04; H10H 29/80

(52) U.S. Cl. CPC G02B 1/16; G02B 1/04; H10H 29/842

(57) ABSTRACT

The present disclosure provides an antistatic coating and a display panel including the same. The antistatic coating includes following raw materials in parts by mass: 20-60 parts of thermoplastic resin selected from at least one of polyester resin, polyurethane, acrylate resin, polycarbonate resin or phenolic resin; 0.1-10 parts of inorganic filler; 0.1-40 parts of antistatic agent selected from at least one of carbon black, graphite, graphene or carbon nanotubes; 0.1-10 parts of thermal curing agent; and 20-80 parts of solvent. The antistatic coating provided by the present disclosure includes carbon-based particles such as carbon black, graphite, graphene and carbon nanotubes, and the carbon-based particles have an excellent thermal conductivity.

### TECHNICAL FIELD

The present disclosure relates to the technical field of display, and particularly, to an antistatic coating and a display panel including the same.

### BACKGROUND

Organic Light-Emitting Diode (OLED) self-luminous display panel emits light controlled by pixel points, that is, each pixel area has a driving pixel circuit, including a circuit switch, a power line ELVSS and a power line ELVDD, etc. The OLED self-luminous display panel can maintain almost the same color gamut for both dark field and bright field pictures, and the color is more accurate. However, when the driving pixel circuit is powered on, it will generate heat, and overheating may adversely affect a life of an OLED light-emitting layer and an electrical property of a thin film transistor (TFT), and increase undesirable risks of a screen producing residual shadows, black spots, burning screens, etc.

FIG. 1 is a schematic structural diagram of an existing OLED self-luminous display panel. In order to increase a strength of the OLED display panel, a double-sided adhesive layer (DST) 9′ is arranged on a surface of a low temperature poly-silico (LTPS) 10′ (substrate) away from a display unit 20′, and a shading adhesive tape (rear tape) 8′ is attached. The display panel also includes a glass paste (frit) 21′ with a closed pattern formed by coating on an edge of a sealing area of the display unit, and an encapsulation layer 30′ and/or a polarizing layer 40′ covering the display unit 20′, etc. The material of the shading adhesive tape 8′ is generally the foam or polyethylene terephthalate (PET), and the foam is a material formed by foaming plastic particles. PET, commonly known as polyester resin, has good heat resistance, mechanical strength and environmental protection performance. However, a thermal conductivity of the foam is 0.03-0.08 W/(m·K), and a thermal conductivity of PET is 0.2 W/(m·K). Correspondingly, a thermal conductivity of the shading adhesive tape 8′ and the double-sided adhesive layer 9′ is 0.2 W/(m·K), which are both low thermal conductivity materials. The foam is a thermal insulation material, which is not conducive to the heat dissipation of the OLED self-luminous display.

It should be noted that the information disclosed in the above background is only used to enhance an understanding of the background of the present disclosure, therefore it may include information that does not constitute the prior art known to those skilled in the art.

### SUMMARY

Aiming at problems in the related art, the present disclosure aims to provide an antistatic coating and a display panel including the same. By adjusting the weight ratio of carbon-based particles such as carbon black, graphite, graphene and carbon nanotubes in the antistatic coating, the reflectivity, the optical density (OD) value and the thermal conductivity of the coating are adjusted, so as to obtain a coating with both an excellent shading effect and an excellent thermal conductivity. When the above coating is applied to a display panel, the obtained coating layer has both a shading effect and a thermal-conducting effect, thereby replacing the shading adhesive tape layer and the double-sided adhesive layer of the display panel in the existing structure and simplifying the manufacturing process of the display panel.

A first aspect of the present disclosure provides an antistatic coating, including following raw materials in parts by mass:
20-60 parts of thermoplastic resin selected from at least one of polyester resin, polyurethane, acrylate resin, polycarbonate resin or phenolic resin;
0.1-10 parts of inorganic filler;
0.1-40 parts of antistatic agent selected from at least one of carbon black, graphite, graphene or carbon nanotubes;
0.1-10 parts of thermal curing agent; and
20-80 parts of solvent.

According to the first aspect of the present disclosure, the antistatic agent is uniformly distributed in the antistatic coating, and/or a thermal conductivity of the antistatic agent is 100 W/(m·k)-5200 W/(m·k).

According to the first aspect of the present disclosure, the antistatic agent is the carbon black, and an amount of the antistatic agent is 13 parts by mass.

A second aspect of the present disclosure provides a display panel, including an antistatic coating layer prepared from the antistatic coating, where the antistatic coating layer is arranged on a surface of a substrate of the display panel away from a display unit.

According to the second aspect of the present disclosure, the antistatic coating layer is prepared through a curing treatment on the antistatic coating, and the curing treatment includes an ultrasonic heating curing, a microwave heating curing, a far infrared thermal curing or an ultraviolet curing.

According to the second aspect of the present disclosure, a thickness of the antistatic coating layer is 5 μm˜100 μm.

According to the second aspect of the present disclosure, a thermal conductivity of the antistatic coating layer is 0.2 W/(m·K).

According to the second aspect of the present disclosure, an amount of the antistatic agent of the antistatic coating layer is 13 parts by mass, and the antistatic agent is carbon black.

According to the second aspect of the present disclosure, a reflectivity of the antistatic coating layer is less than 5.5%, and/or an optical density (OD) value of the antistatic coating layer is greater than 3.

According to the second aspect of the present disclosure, a resistance of the antistatic coating layer is 10⁶Ω to 10⁹Ω.

The antistatic coating of the present disclosure includes at least one kind of carbon-based particles such as carbon black, graphite, graphene and carbon nanotubes, and the carbon-based particles have an excellent thermal conductivity. By adjusting a proportion of the carbon-based particles in the antistatic coating, the antistatic coating layer has a good reflectivity and an optical density value, so that the display panel can obtain a coating with both an excellent shading effect and an excellent thermal conductivity, which can replace the shading adhesive tape layer and the double-sided adhesive layer of the display panel in the existing structure and simplify the manufacturing process of the display panel.

### BRIEF DESCRIPTION OF THE DRAWINGS

The accompanying drawings, which are incorporated in and constitute a part of this specification, illustrate embodiments consistent with the present application and are used in conjunction with the specification to explain the principles of the present application. Other features, purposes and advantages of present disclosure will become more apparent by reading the detailed description of the non-restrictive embodiments with reference to the following accompanying drawings. Obviously, the drawings in the following description are only some embodiments of the present disclosure. For those of ordinary skill in the art, other drawings can also be obtained from these drawings without paying creative effort. In addition, the drawings are only schematic illustrations of the present disclosure and are not necessarily drawn to scale. In the drawings, the same reference sign indicates the same or similar part, and repeated descriptions thereof will be omitted. Some of the block diagrams shown in the drawings are functional entities and do not necessarily correspond to physically or logically independent entities.

FIG. 1 is a schematic structural diagram of an existing display panel; and

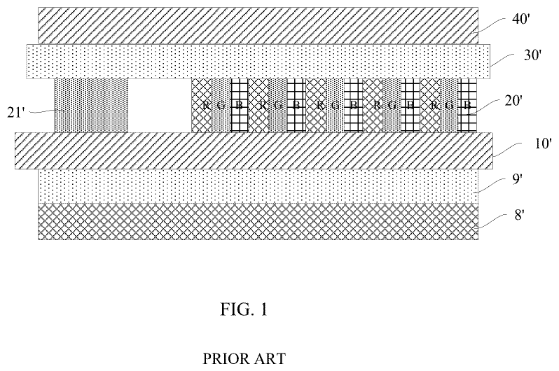

FIG. 2 is a schematic structural diagram of a display panel according to an embodiment of the present disclosure.

### REFERENCE SIGNS

8′ shading adhesive tape
9′ double-sided adhesive layer
10′, 10 substrate
20′, 20 display unit
21′, 21 glass cement
30′, 30 encapsulation layer
40′, 40 polarizing layer
90 antistatic coating layer

### DETAILED DESCRIPTION

Exemplary embodiments will now be described more fully with reference to the accompanying drawings. However, exemplary embodiments can be embodied in various forms and should not be construed as limited to the examples set forth herein. On the contrary, these embodiments are provided so that the present disclosure will be more thorough and complete, and will fully convey the concepts of exemplary embodiments to those skilled in the art. The described features, structures, or characteristics may be combined in any suitable manner in one or more embodiments.

In the representation of this specification, the representations of the reference terms “one embodiment”, “some embodiments”, “example”, “specific example”, “some examples” or the like mean that the specific features, structures, materials or characteristics represented in combination with this embodiment or example are included in at least one embodiment or example of this specification. Moreover, the specific features, structures, materials or characteristics represented may be combined in any one or more embodiments or examples in a suitable manner. In addition, those skilled in the art may combine and integrate different embodiments or examples and features of different embodiments or examples represented in this specification if there is no contradiction therebetween.

Throughout the specification, when a device is said to be “connected” to another device, this includes not only the case of “direct connection”, but also the case of an “indirect connection” in which other element is placed between them. Terms indicating relative spaces such as “below” and “above” may be used to more easily explain a relationship between one device and another device illustrated in the drawings. Such terms refer to not only the meaning indicated in the drawings, but also other meanings or operations of the apparatus in use. For example, if the apparatus in the drawing is turned over, a device that was described as “below” other device(s) is described as “above” other device(s). Therefore, the exemplary term of so-called “below” include both “above” and “below”. The apparatus may be rotated by 90° or other angles, and the terms representing relative space are interpreted accordingly.

In some examples, although the terms “first”, “second” and the like are used herein to represent various elements, these elements should not be limited by these terms. These terms are only used to distinguish one element from another, for example, the representations of the first interface and the second interface. Furthermore, as used herein, the singular forms “a/an”, “one” and “the” are intended to also include the plural forms, unless the context indicates to the contrary. It should be further understood that the terms “containing” and “including” indicate the presence of features, steps, operations, elements, components, items, categories and/or groups, but do not exclude the presence, appearance or addition of one or more other features, steps, operations, elements, components, items, categories and/or groups. The terms “or” and “and/or” as used herein are to be interpreted as inclusive or mean any one or any combination. Therefore, “A, B or C” or “A, B and/or C” means “any of the following: A; B; C; A and B; A and C; B and C; A, B and C”. An exception to this definition occurs only when a combination of elements, functions, steps or operations are inherently mutually exclusive in some way.

Although not defined differently, all terms, including the technical terms and the scientific terms used herein, have the same meaning as commonly understood by those skilled in the art to which the present specification belongs. The terms defined in commonly used dictionaries are additionally interpreted as having meanings consistent with the contents of the relevant technical literature and the current tips. As long as they are not defined, the terms shall not be excessively interpreted as ideal or very formulaic meanings.

The present disclosure provides an antistatic coating and a display panel including the same. The antistatic coating includes the following raw materials in parts by mass: 20-60 parts of thermoplastic resin, where the thermoplastic resin is selected from at least one of polyester resin, polyurethane, acrylate resin, polycarbonate resin or phenolic resin; 0.1-10 parts of inorganic filler; 0.1-40 parts of antistatic agent selected from at least one of carbon black, graphite, graphene or carbon nanotubes; 0.1-10 parts of thermal curing agent; and 20-80 parts of solvent. The antistatic coating of the present disclosure includes at least one kind of carbon-based particles such as carbon black, graphite, graphene or carbon nanotubes, and the carbon-based particles have an excellent thermal conductivity. By adjusting a proportion of the carbon-based particles in the antistatic coating, the antistatic coating layer has a good reflectivity and a good optical density value, so that the display panel can obtain a coating with both an excellent shading effect and an excellent thermal conductivity, which can replace the shading adhesive tape layer and the double-sided adhesive layer of the display panel in the existing structure and simplify a manufacturing process of the display panel.

In the following, the antistatic coating of the present disclosure and the display panel including the antistatic coating are further described with reference to the drawings and specific embodiments. It can be understood that each specific embodiment is not taken as a limitation of the protection scope of the present disclosure.

The antistatic coating of the present disclosure includes the following raw materials in parts by mass: 20-60 parts of thermoplastic resin, which is selected from at least one of polyester resin, polyurethane, acrylate resin, polycarbonate resin or phenolic resin; 0.1-10 parts of inorganic filler, and the inorganic filler may be the following:
0.1-40 parts of antistatic agent selected from at least one of carbon black, graphite, graphene or carbon nanotubes; 0.1-10 parts of thermal curing agent; and 20-80 parts of solvent.

Specifically, 40 g of polyester resin (hydroxyl value=8 mgKOH/g), 30 g of triethylene glycol monomethyl ether and 20 g of propylene glycol methyl ether acetate are put into a reaction bottle with a fixed stirrer, a heater and nitrogen, and a stirring is started. The stirring speed is 80 rpm, the temperature is raised to 60° C., and the mixture is stirred for 12 h. After the resin is completely dissolved, 2.5 g of fumed silica (inorganic filler), 2.0 g of conductive carbon black CABOT BP 2000 (antistatic agent), 1.0 g of isocyanate curing agent (Wanhua HT-100), and 0.3 g of polyether modified dimethyl polysiloxane (leveling agent BYK-331) are added and stirred for 30 min, and then the experiment was finished. The product is ground by a horizontal grinder to make it evenly dispersed, and a thermosetting antistatic coating was obtained. Samples 1 #to 6 #below are all obtained by the above method.

In some embodiments, a thermal conductivity of the antistatic agent may be between 100 W/(m·K) and 5200 W/(m·K) by selecting different components. At the same time, in order to improve an uniformity of the subsequent coating layer obtained from the coating, the coating itself should have a certain uniformity, including an uniform thermal conductivity and an uniform light transmittance, and accordingly, the antistatic agent such as carbon black, graphite, graphene and carbon nanotubes should be uniformly distributed in the antistatic coating.

Further, it is found through the experiment that when the antistatic agent is the carbon black, it is easier to adjust a color of the coating layer to black via the carbon black. Therefore, a shading performance and a thermal conductivity of the antistatic coating can be optimized by further adjusting a proportion of the carbon black in the antistatic coating. Preferably, the carbon black in the coating layer is 13 parts by mass.

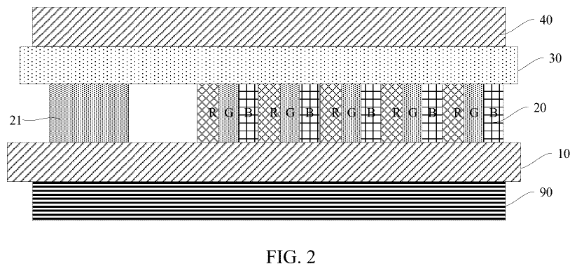

The antistatic coating of the present disclosure has both excellent shading effect and excellent thermal conductivity. When the coating is applied to the display panel, it may replace the shading adhesive tape layer and the double-sided adhesive layer of the display panel in the existing structure, and simplify a manufacturing process of the display panel. The present disclosure also provides a display panel, which includes an antistatic coating layer prepared from the antistatic coating. FIG. 2 is a structural schematic diagram of the display panel according to an embodiment of the present disclosure. Specifically, the display panel includes a substrate 10, a display unit 20, a glass paste 21 with a closed pattern formed by coating on an edge of a sealing area of the display unit 20, and an encapsulation layer 30 and/or a polarizing layer 40 covering the display unit 20. The substrate 10 of the display panel may be low-temperature polysilicon, and a surface of the substrate away from the display unit 20 is provided with an antistatic coating layer 90.

The antistatic coating layer 90 may be obtained through a curing treatment on the antistatic coating. Specifically, the antistatic coating may be coated on a surface of the substrate 10 facing away from the display unit 20 by the spin coating, etc., and then liquid antistatic coating is cured by the curing treatment such as ultrasonic heating curing, microwave heating curing, far infrared heating curing or ultraviolet curing. A thickness of the cured antistatic coating layer may be controlled by adjusting process parameters such as a density of the antistatic coating itself and a thickness of the coated antistatic coating. Preferably, the thickness of the antistatic coating layer is 5 μm˜100 μm. The thermal conductivity of the antistatic coating layer is 0.2 W/(m·K), that is, the antistatic coating layer has an excellent thermal conductivity.

In an embodiment, when the carbon black is selected as the antistatic agent, the part by mass of the antistatic agent is adjusted to 13. When the thickness of the antistatic coating layer is between 7 μm-15 μm, the reflectivity of the antistatic coating layer is less than 5.5%, and the optical density (OD) value of the antistatic coating layer is greater than 3. At this time, the antistatic coating layer achieves the best shading effect and the best heat conduction effect. At the same time, a resistance of the antistatic coating layer may be controlled at 10⁶Ω˜10⁹Ω. That is, the antistatic coating layer has excellent antistatic effect, which can improve a tearing electrostatic (Mura) phenomenon of the display panel.

Further, the display panel prepared in this embodiment (the carbon black as the antistatic agent, 13 parts by mass) was compared with the existing display panel. Table 1 shows a data list of the reliability test of the adhesion of the antistatic coating layer prepared from the antistatic coating of the present disclosure, Table 2 shows a comparative data list of the antistatic performance of the antistatic coating layer, and Table 3 shows a comparative data list of the measured heating temperatures of the existing display panel and the display panel of the present disclosure.

Table 1 shows the reliability test data of the adhesion of the antistatic coating layer prepared from the antistatic coating of the present disclosure.

| | | | Temperature | | |
|---|---|---|---|---|---|
| | | | and humidity | | |
| | | | test (85° | Temperature | Salt |
| Test name | UV cross-cut test | | C./85% RH) | shock test | spray |
| Test | LED light | Mercury lamp | 240H | 100 cycles | 24H |
| frequency | 9000 | 4750 | | | |
| | mJ/cm² | mJ/cm² | | | |
| | 3 times | 3 times | | | |
| Test | 20 | 20 | 20 | 20 | 20 |
| quantity/piece | | | | | |

| | |
|---|---|
| Test standard | Adhesion ≥ 3B |
| Test data | Adhesion ≥ 3B |

Table 2 shows the comparison of the antistatic performance between the existing antistatic coating layer and the antistatic coating layer of the present disclosure.

| | | | | Antistatic | |
|---|---|---|---|---|---|
| | | | Existing | coating | |
| | | | antistatic | layer of | |
| | | Test | coating | the present | |
| Test item | | standard | layer | disclosure | Conclusion |
| Antistatic | Tearing | ≤500 | 150 | 100 | The antistatic |
| performance | voltage (V) | | | | performance |
| | Friction | ≤100 | 80 | 45 | of the |
| | voltage (V) | | | | antistatic |
| | Surface | 10⁶~10⁹ | 10¹⁰ | 10⁷ | coating layer |
| | resistance | | | | of the present |
| | (Ω/cm) | | | | disclosure is |
| | Electrostatic | Lighting | Yes | No | superior to |
| | Mura | visual | | | that of the |
| | | inspection | | | existing |
| | | | | | display panel |

Table 3 is the comparison data of the measured heating temperatures of the existing display panel and the display panel of the present disclosure.

| | | Existing | Display panel of the |
|---|---|---|---|
| Heating temperature | | display panel | present disclosure |
| Light | Sample 1# | 31.6° C. | 28.2° C. |
| for 2H | Sample 2# | 31.8° C. | 28.6° C. |
| | Sample 3# | 31.3° C. | 28.1° C. |
| | Sample 4# | 32.1° C. | 28.9° C. |
| | Sample 5# | 31.9° C. | 28.4° C. |
| | Sample 6# | 31.6° C. | 28.5° C. |

| | | |
|---|---|---|
| Testing equipment | Infrared | Infrared |
| | thermometer TiS65 | thermometer TiS65 |
| Ambient (laboratory) | 25° C. | 25° C. |
| temperature | | |

It can be seen from Table 1 that the antistatic coating of the present disclosure can meet a requirement of adhesion in practical use. At the same time, in terms of heat dissipation performance, the heat generated by the display panel of the present disclosure is lower than that of the existing display panel, as shown in Table 3, which further proves that the antistatic coating layer of the present disclosure has a good heat dissipation performance and at the same time has a shading effect.

The above are further detailed descriptions of the present disclosure combined with specific preferred embodiments, and it cannot be considered that the specific implementation of the present disclosure is limited to these descriptions. It is obvious to those skilled in the art that this application is not limited to the details of the above-mentioned exemplary embodiments, and this application can be realized in other specific forms without departing from the spirit or basic characteristics of this application. Therefore, the embodiments should be considered in all aspects as exemplary and non-limiting, and the scope of this application is defined by the appended claims rather than the above descriptions, so it is intended to embrace all changes that fall within the meaning and range of equivalents of the claims. Any reference signs in the claims shall not be construed as limiting the claims involved.

1. An antistatic coating, comprising following raw materials in parts by mass:
20-60 parts of thermoplastic resin selected from at least one of polyester resin, polyurethane, acrylate resin, polycarbonate resin or phenolic resin;
0.1-10 parts of inorganic filler;
0.1-40 parts of antistatic agent selected from at least one of carbon black, graphite, graphene or carbon nanotubes;
0.1-10 parts of thermal curing agent; and
20-80 parts of solvent.

2. The antistatic coating according to claim 1, wherein the antistatic agent is uniformly distributed in the antistatic coating, and/or a thermal conductivity of the antistatic agent is 100 W/(m·k)-5200 W/(m·k).

3. The antistatic coating according to claim 1, wherein the antistatic agent is the carbon black, and an amount of the antistatic agent is 13 parts by mass.

4. A display panel, comprising an antistatic coating layer prepared from an antistatic coating, wherein the antistatic coating layer is arranged on a surface of a substrate of the display panel away from a display unit, wherein the antistatic coating comprises following raw materials in parts by mass:
20-60 parts of thermoplastic resin selected from at least one of polyester resin, polyurethane, acrylate resin, polycarbonate resin or phenolic resin;
0.1-10 parts of inorganic filler;
0.1-40 parts of antistatic agent selected from at least one of carbon black, graphite, graphene or carbon nanotubes;
0.1-10 parts of thermal curing agent; and
20-80 parts of solvent.

5. The display panel according to claim 4, wherein the antistatic coating layer is prepared through a curing treatment on the antistatic coating, and the curing treatment comprises an ultrasonic heating curing, a microwave heating curing, a far infrared heating curing or an ultraviolet curing.

6. The display panel according to claim 4, wherein a thickness of the antistatic coating layer is 5 μm˜100 μm.

7. The display panel according to claim 4, wherein a thermal conductivity of the antistatic coating layer is 0.2 W/(m·K).

8. The display panel according to claim 4, wherein an amount of the antistatic agent of the antistatic coating layer is 13 parts by mass, and the antistatic agent is carbon black.

9. The display panel according to claim 8, wherein a reflectivity of the antistatic coating layer is less than 5.5%, and/or an optical density (OD) value of the antistatic coating layer is greater than 3.

10. The display panel according to claim 8, wherein a resistance of the antistatic coating layer is 10⁶Ω˜10⁹Ω.

11. The display panel according to claim 4, wherein the antistatic agent is uniformly distributed in the antistatic coating, and/or a thermal conductivity of the antistatic agent is 100 W/(m·k)-5200 W/(m·k).
